(19) United States
(12) Patent Application Publication
(10) Pub. No.: US 2016/0372512 A1
(43) Pub. Date: Dec. 22, 2016

(54) METHOD FOR FORMING PAD OF WAFER

(71) Applicant: SILICONFILE TECHNOLOGIES INC., Gyeonggi-do (KR)

(72) Inventor: Heui Gyun AHN, Gyeonggi-do (KR)

(21) Appl. No.: 14/902,085

(22) PCT Filed: Apr. 30, 2014
(86) PCT No.: PCT/KR2014/003828

§ 371 Date: Dec. 30, 2015

(30) Foreign Application Priority Data
Jul. 8, 2013 (KR) 10-2013-0079549

(51) Int. Cl. H01L 27/146; H01L 21/683

(52) U.S. Cl. CPC H01L 27/14687; H01L 27/1464; H01L 21/6835; H01L 27/14636; H01L 27/14685; H01L 2221/6834

(57) ABSTRACT

The present invention relates to a technology for simply performing a process of forming a pad on the rear surface of a via hole in a packing process in a process of forming a pad of a wafer. The present invention is characterized by a packing process in a process for manufacturing a wafer, the packing process comprising the steps of: attaching glass to the upper portion of a micro lens and then separating a handling wafer from an element wafer, thereby exposing metal layers formed on the element wafer to the outside; and forming pads for the metal layers.

### TECHNICAL FIELD

The present invention relates to a technology for forming a pad of a wafer, and more particularly, to a method for simply performing a process of forming a pad of a wafer such that an element formed in an element wafer is not influenced on a plasma by omitting a plasma process.

### BACKGROUND ART

A stacking technology of a wafer would be a core technology of a high end semiconductor of a next generation. Thus, a research and development for a stacking of a wafer has been actively performed in an each field.

Recently, major one of the stacking technologies of the wafer is a technology of forming a logic wafer in which a peripheral circuit is formed. For example, a back side illumination (it is referred to as ‘BSI’) is a technology of forming a pad after a process for bonding a handling wafer with a sensor wafer of forming a light receiving element.

Referring to a method for forming a pad of a wafer according to a conventional technology, a pre-process including an epitaxial (EPI) growth process and an annealing process is performed on a silicon substrate, e.g., a silicon-on-insulator (SOI) wafer, and a post-process including a laminating process of a handling wafer and an element wafer and a back side thinning process is performed. Then, after an anti-reflection coating, a color filter and a micro lens are formed, a packaging process is performed.

However, in the packaging process, after a glass and an element wafer on which a peripheral circuit is formed are bonded, a back side thinning process on a handling wafer, e.g., a silicon layer, which is formed in the element wafer, is performed. Subsequently, a via hole is formed by performing an etching process on the back side thinned silicon layer, and a pad is formed on a backside of the via hole.

As described above, in the method for forming the pad of the wafer according to the conventional technology, since the glass and the element wafer are bonded, the back side thinning process is performed on the silicon layer formed in the element wafer, the etching process is performed on the back side thinned silicon layer, the vis is formed and the pad is formed on the back side of the via, the number of processes is increased, and a wafer manufacturing cost and time is increased.

Moreover, a plasma is requested to perform the etching on the silicon layer, and the plasma generated in the plasma process has a bad influence on the element formed in the element wafer.

### DISCLOSURE

### Technical Problem

Various embodiments of the present invention are directed to a method for simply performing a process of forming a pad on a back side of a via hole in a packing process in a process of forming a pad of a wafer.

Various embodiments of the present invention are directed to a method for simply performing a process of forming a pad of a wafer such that an element formed in an element wafer is not influenced on a plasma by omitting a plasma process.

### Technical Solution

In accordance with an embodiment of the present invention, a method for forming a pad of a wafer includes steps of: performing a pre-process to from and distribute an element or a circuit on a substrate; performing a post-process to bond a handling wafer and an element wafer in which a light receiving element is formed, and to perform a bank side thinning process; sequentially forming a color filter and a micro lens on an upper portion of the element wafer after the post-process is performed; attaching a glass on an upper portion of the micro lens, separating the handling wafer from the element wafer, and exposing metal layers, which are formed in the element wafer, outside; and forming pads for the metal layers.

### Advantageous Effects

A method for forming a pad of a wafer in accordance with embodiments of the present invention is simplified by directly forming pads on metal layers in an element wafer, which is exposed outside, after the handling wafer is separated from the element wafer in a process of forming a pad of a wafer.

Moreover, an element formed in an element wafer is not influenced on a plasma by omitting a plasma process.

### DESCRIPTION OF DRAWINGS

FIGS. 1 to 4 illustrate cross sectional views of a wafer in each process according to a method for forming a pad of a wafer of the present invention.

FIG. 5 illustrates a process flow on a method for forming a pad of a wafer of the present invention.

FIG. 6a and FIG. 6b illustrate cross sectional views of a wafer in a package process of a method for forming a pad in accordance with an embodiment of the present invention.

FIG. 6c and FIG. 6d illustrate cross sectional views of a wafer in a package process of a method for forming a pad in accordance with another embodiment of the present invention.

FIG. 7 illustrates a cross sectional view of a pad formed using a re-distribution layer in accordance with another embodiment of the present invention.

### BEST MODE

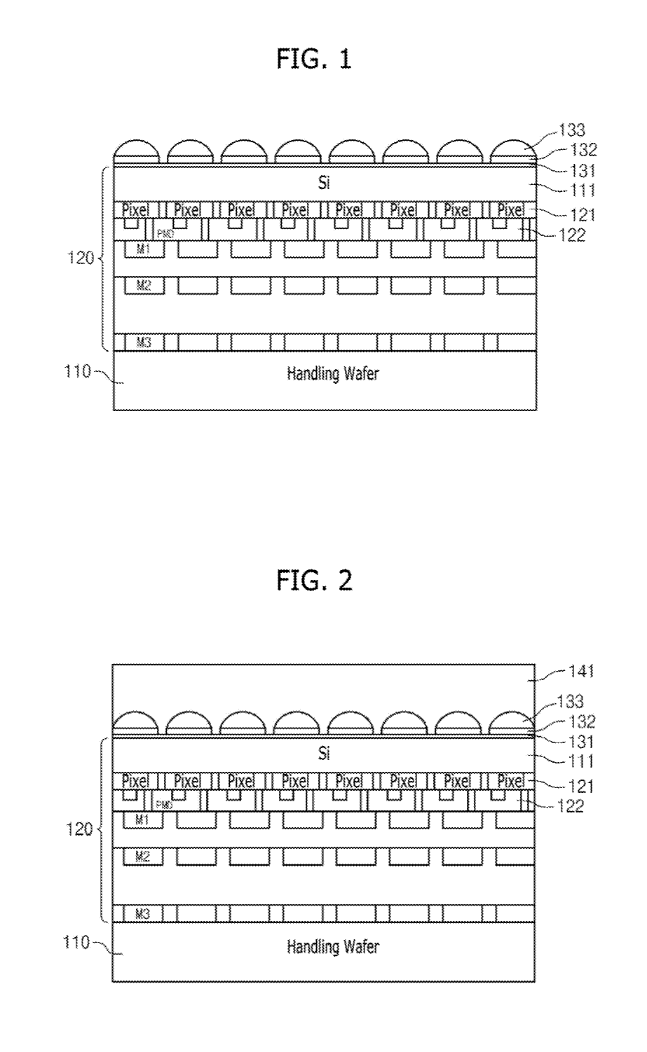

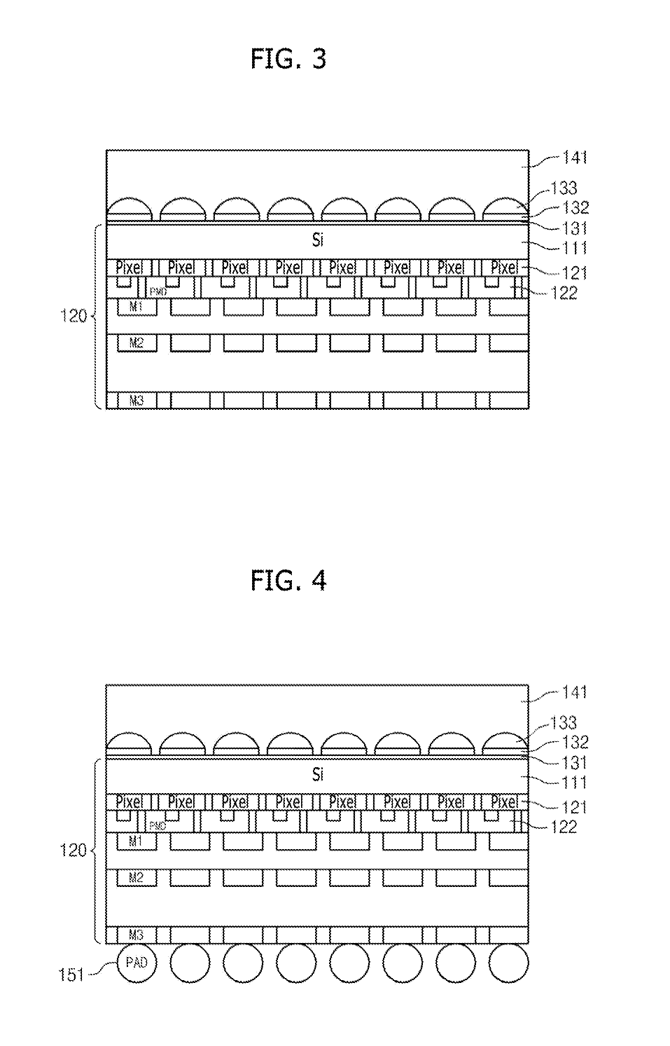

Hereinafter, various embodiments will be described below in more detail with reference to the accompanying drawings. FIGS. 1 to 4 illustrate cross sectional views of a wafer in each process according to a method for forming a pad of a wafer of the present invention. FIG. 5 illustrates a process flow on a method for forming a pad of a wafer of the present invention.

Firstly, referring to FIG. 1, a pre-process is performed to form and distribute an element or a circuit on a substrate 111, e.g., a silicon substrate at a step S1.

Subsequently, post-process is performed to bond a handling wafer 110, e.g. a silicon layer, with an element wafer 120 on which a light receiving element such as a photo diode is formed, and to perform a back side thinning process at a step S2.

Then, an anti-reflection (AR) coating 131, a color filter 132 and a micro lens 133 are sequentially formed on an upper portion of the element wafer 120 on which the post-process is performed as described above at a step S3.

Next, a packaging process is performed. Herein, a glass 141 is attached on an upper portion of the micro lens 133 as shown in FIG. 2 at a step S4.

Especially, an entire thickness including the glass 141 and the element wafer 120 except the handling wafer 110 becomes thick to perform a pad deposition process by bonding the glass 141 on the upper portion of the micro lens 133 as described above.

As considering this condition, a back side thinning process or a process for forming a via hole on a back side thinned handling wafer 110 is not performed for a pad deposition of the wafer after the glass 141 is bonded. As shown in FIG. 3, the handling wafer 110 is clearly removed or de-bonded from the element wafer 120, and a metal layer M3 formed in the element wafer 120 is exposed outside at a step S5.

Under the above-described state, as shown in FIG. 4, a process for forming a pad 151 on the metal layer M3 formed in the element wafer 120 is performed at a step S6.

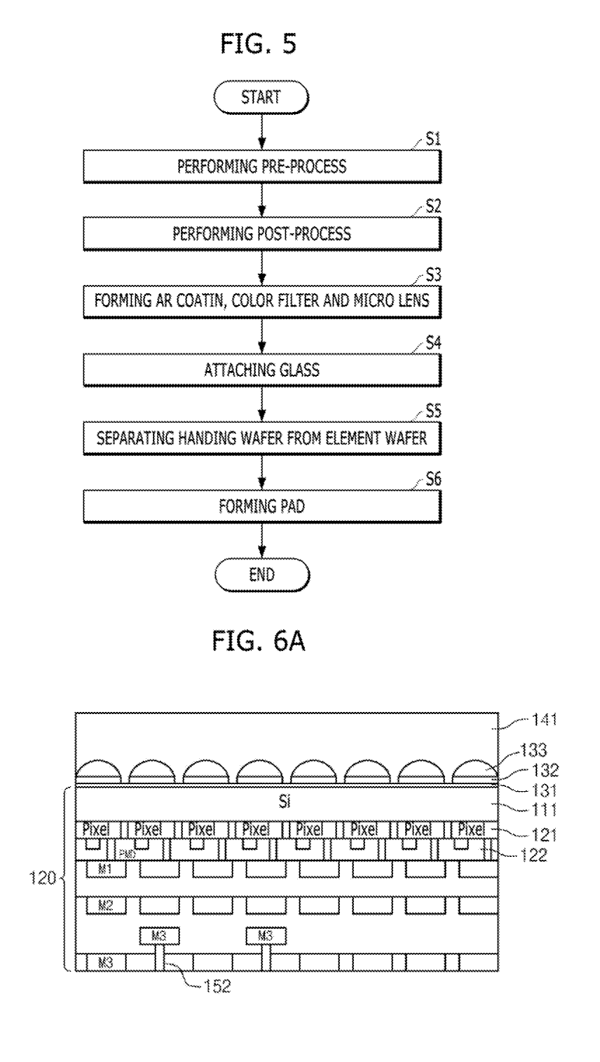

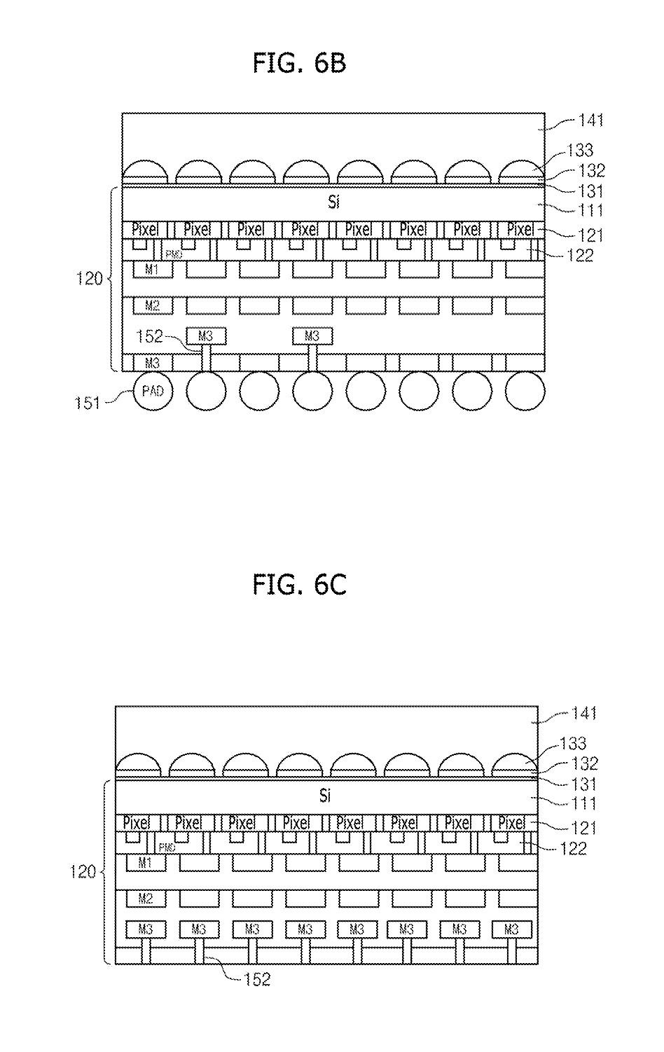

FIG. 6a and FIG. 6b illustrate cross sectional views of a wafer in a package process of a method for forming a pad in accordance with an embodiment of the present invention.

Referring to FIGS. 6a and 6b, as shown in FIG. 3, in case that metal layers M3 formed in the element wafer 120 are exposed outside by wholly removing or de-bonding the handling wafer 110 from the element wafer 120, if the metal layer M3 are formed in not a same horizontal plane but at least two layers of the element wafer 120, the metal layers M3 formed in the outermost layer is exposed outside by a removing operation or a de-bonding operation of the handling wafer 110.

However, since the metal layers M3 formed in the inside of the outermost layer are not exposed outside by the removing operation or the de-bonding operation of the handling wafer 110, the metal layers M3 formed in the inside of the outermost layer and the metal layers M3 formed in the outermost layer may be not formed by a same process.

In this case, as shown in FIG. 6a, via-spaces 152 are formed by performing an etching process on the metal layers M3 formed inside the outermost layer.

There are various processes for forming the via-spaces 152. For example, the via-spaces 152 may be formed by spreading a dielectric material such as oxide or nitride on a backside of a pad and performing a photo lithography process.

Then, as shown in FIG. 6b, pads 151 are formed on the metal layers M3 which are exposed outside, and the metal layers M3, which are not exposed outside, are connected to the pads 151 through the via-spaces 152.

FIG. 6c and FIG. 6d illustrate cross sectional views of a wafer in a package process of a method for forming a pad in accordance with another embodiment of the present invention.

As FIG. 6c and FIG. 6d are compared with FIG. 6a and FIG. 6b, differently from metal layers M3, which are disposed in at least two layers, shown in FIG. 6a and FIG. 6b, the metal layers M3 are formed inside the outermost layer and are connected to the pads 151 through the via-spaces 152 after the via-spaces 152 are formed.

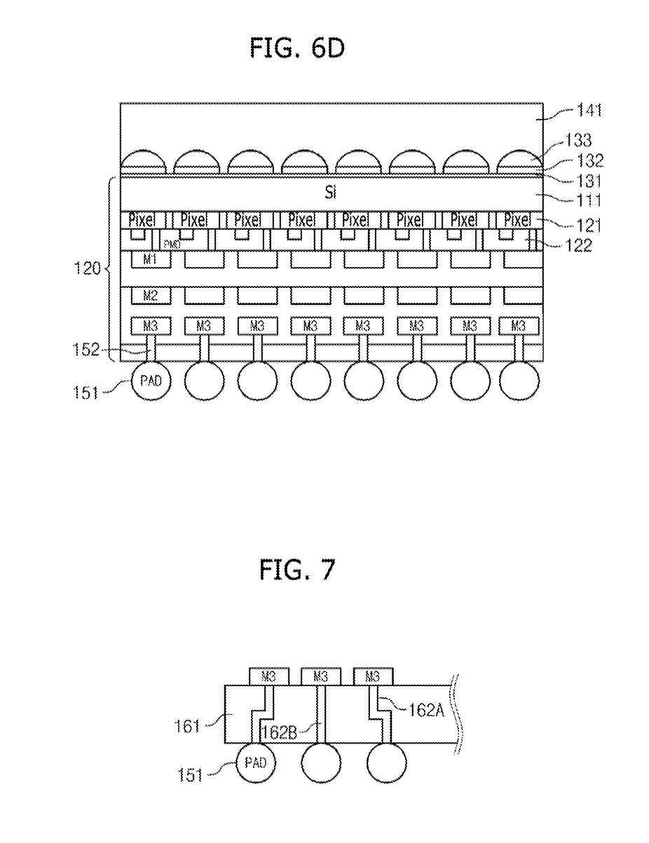

FIG. 7 illustrates a cross sectional view of a pad formed using a re-distribution layer in accordance with another embodiment of the present invention. After the metal layers M3 is exposed outside by clearly removing or de-bonding the handling wafer 110 from the element wafer 120, in case that a pad forming space is not acquired when the pads 151 are formed on the metal layers M3, the pad forming space is acquired using a re-distribution layer (RDL).

Referring to FIG. 7, after the metal layers M3 formed in the element wafer 120 is exposed outside by clearly removing or de-bonding the handling wafer 110 from the element wafer 120, the RDL 161 is formed on the backside of the metal layer M3.

Subsequently, the via-spaces for connecting the metal layers M3 to the pads 151 are formed in the RDL 161. Herein, at least one curved type via-space 162A is formed such that an interval between the pads 151 is wider than an interval between the metal layers M3. A bar type via-space 162B may be additionally formed in the RDL.

Thus, when the pads 151 are formed on the metal layers M3, in an even case that the a pad forming space is not acquired, the pads 151 connected to the metal layers M3 are formed using the via-spaces 161 and 162, which are formed as described above.

Although various embodiments have been described for illustrative purposes, it will be apparent to those skilled in the art that various changes and modifications may be made without departing from the spirit and scope of the invention as defined in the following claims.

What is claimed is:

1. A method for forming a pad of a wafer, comprising steps of:
(a) performing a pre-process to from and distribute an element or a circuit on a substrate;
(b) performing a post-process to bond a handling wafer and an element wafer in which a light receiving element is formed, and to perform a bank side thinning process;
(c) sequentially forming a color filter and a micro lens on an upper portion of the element wafer after the post-process is performed;
(d) attaching a glass on an upper portion of the micro lens, separating the handling wafer from the element wafer, and exposing metal layers, which are formed in the element wafer, outside; and
(e) forming pads for the metal layers.

2. The method for forming the pad of the wafer of claim 1, wherein the (d) step includes using a de-bonding for separating the handling wafer from the element wafer.

3. The method for forming the pad of the wafer of claim 1, wherein the (e) step includes
forming a via-space by performing an etching process on the metal layers formed inside the element wafer after the (d) step is formed; and
forming the pads for the metal layers, which are exposed outside and connecting the metal layers, which are formed inside the element wafer, to the pads through via-spaces after the (d) step is formed.

4. The method for forming the pad of the wafer of claim 3, wherein the (e) step includes performing a photo lithography process after a dielectric material of oxide or nitride is spread on a back side of the pads to form the via-spaces.

5. The method for forming the pad of the wafer of claim 1, wherein the (e) step includes acquiring a pad forming space using a re-distribution layer (RDL) in case that the pad forming space is not formed due to a narrow interval between the metal layers.

6. The method for forming the pad of the wafer of claim 5, wherein the (e) step includes
forming the RDL on a back side of the metal layers after the metal layers formed in the element wafer are exposed;
forming via holes for connecting the metal layers to the pads in the RDL, wherein the via holes have at least one curved type via-space such that an interval between the pads is wider than an interval between the metal layers; and
forming the pads connected to the metal layers using the via-space.

7. The method for forming the pad of the wafer of claim 6, wherein the step of forming the at least one curved type via-space includes additionally a bar type via-space.
